(19) United States
(12) Patent Application Publication
(10) Pub. No.: US 2008/0136490 A1
(43) Pub. Date: Jun. 12, 2008

(54) Voltage Integrator And Transformer Provided With Such An Integrator

(75) Inventor: Paul Johannes Marie Julicher, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/814,681

(22) PCT Filed: Jan. 25, 2006
(86) PCT No.: PCT/IB06/50267

§ 371 Date: Jul. 25, 2007

(30) Foreign Application Priority Data
Jan. 28, 2005 (EP) 05100572.6

(51) Int. Cl. G06G 7/184; G01R 33/00

(52) U.S. Cl. 327/344; 324/200

(57) ABSTRACT

A voltage integrator, comprising a resistor (4) and a capacitor (5) connected in series between an input voltage (V) and ground, wherein the resistance (R) of said resistor and the capacitance (C) of said capacitor are adapted such that a voltage (Vc) across said capacitor approximates the integral of said input voltage (V). Means are provided for preventing said capacitor voltage (Vc) from falling below a lower limit, preferably zero, thereby ensuring automatic initialization of the integrator after each integration cycle.

The present invention relates to a voltage integrator, comprising a resistor and a capacitor connected in series between an input voltage and ground, wherein the resistance of said resistor and the capacitance of said capacitor are adapted such that a voltage across said capacitor approximates the integral of said input voltage.

When using such a capacitive integrator circuit, it is often required to initialize the output voltage of this integrator at the start of the integrating interval. One example is when the magnetic flux in a transformer of a switched mode power supply is to be measured. As is well known, this flux can be determined by integrating the voltage across any transformer winding. If the integrator is not initialized at the start of each switching cycle of the power supply, the integrator output waveform still resembles the flux waveform. However, the position of this integrator output waveform with respect to ground does not reflect the actual flux.

Normally, this initialization is performed by a switching element connected in parallel to the capacitor, which discharges the capacitor at the beginning of each period. This switching element must be driven by an additional control circuit, which in turn needs to be synchronized with the switching frequency of the power supply. Examples of such control, and the difficulties related thereto are described in Halbleiter Schaltungstechnik, U. Tietze & Ch. Schenk, Springer Verlag, 1986. Two of the basic issues are that the initializing speed is limited by RC discharge times and/or the switching times of the switch element used, and that the (periodic) control of the switching element providing the initialization is difficult.

Available solutions to these problems are complex and expensive. Further, most integrators use a floating integrating capacitor, which has no permanent connection to ground, making accurate control even more difficult. In summary, satisfactory integrator initialization by means of traditional schemes requires complex and expensive circuitry.

It is an object of the present invention to overcome these problems, and to provide an integrator circuit where initialization is accomplished without any switching element as described in the prior art.

A further object of the invention is to provide integrator initialization with satisfactory performance that is simple to implement and cost efficient.

These and other objects are achieved with an integrator of the kind mentioned in the introduction, further comprising means for preventing said capacitor voltage from falling below a lower limit.

According to the invention, the integration is performed by a simple RC filter, which has been dimensioned to approximate a true integrator. As the RC-filter is connected to ground, problems with a floating capacitor are avoided. Further, means are arranged to prevent the capacitor voltage from falling below a lower limit, thus securing a minimum voltage across the capacitor.

The invention is based on the insight that by regulating the minimum capacitor voltage to a predetermined level, automatic initialization of the integrator output voltage is accomplished after each integration cycle. This initialization is a non-switched method, eliminating all the problems associated with the classical methods including a switching element in parallel with the capacitor.

If the means for preventing the capacitor voltage from falling below a lower limit are implemented in an IC, the use of the simple RC integrator is very beneficial. Because of the grounded capacitor used in the integrator, only one pin of the IC is required to connect the resistor and capacitor to the IC. Conventional integrators, with a floating capacitor, require two pins. Although there are other integrator solutions using a grounded capacitor, they typically include several resistors and capacitors, which have to be matched to each other in order to provide satisfactory performance. Such solutions are not practical to implement in an IC.

Preferably, the RC time constant is significantly larger than the interval of the signal to be integrated. For example, the time constant can be 5-10 times larger.

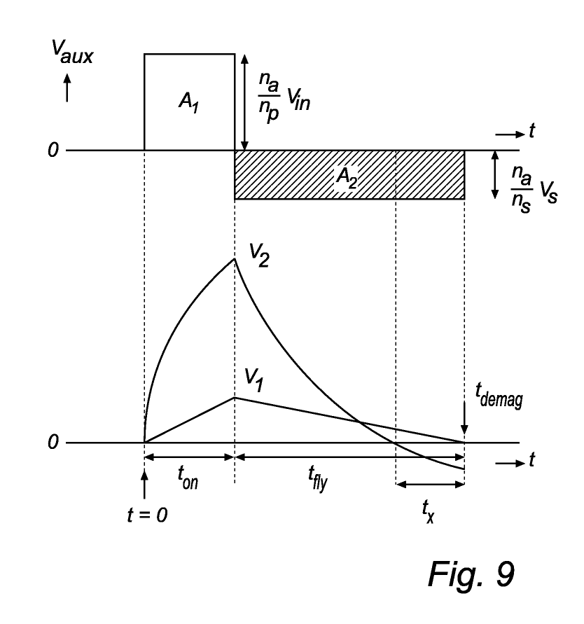

In many applications, such as the mentioned flux measurement, the signal to be integrated is a periodic signal. In this case, each period includes an interval to be integrated. In between these integrating intervals, the integrator is initialized, as mentioned above. Such a dimensioning of the resistance and capacitance will ensure that the resistor acts like a constant current source during the signal period, so that the voltage across the capacitor will rise and fall linearly. The RC filter will then very closely approximate an integrator. This is illustrated in FIG. 9, showing the integration of a winding voltage Vₐᵤₓ from a flyback converter during the period the primary switch S is switched ON (tₒₙ) and during the flyback stroke (t_{fly}). It is physically determined that the areas A₁ and A₂ in the Vₐᵤₓ voltage are equal (the average Vₐᵤₓ measured during tₒₙ+t_{fly} equals 0). Therefore, if we integrate Vₐᵤₓ during tₒₙ+t_{fly}, the end value of the integrator output equals the start value. The waveform V₁ represents the ideal case, in which the integrator is a true integrator. This case can be obtained if RC>>(tₒₙ+t_{fly}). The waveform V₂ represents a non-ideal case, in which RC is chosen much too small, and the V₂ waveform therefore becomes exponential instead of linear. Furthermore, as V₂ is not really an integral of the voltage Vₐᵤₓ, it crosses zero far before the actual instant at which the transformer is demagnetized (t_{demag}). This error is indicated in FIG. 9 by tₓ.

A further advantage with this dimensioning of the RC filter, is that the filter will act as a low pass filter and effectively damps any high frequency content in the signal to be integrated. This is especially of importance when implementing the integrator for measuring the magnetic flux in a self-oscillating flyback converter, as any sinusoidal content in the winding voltage will be damped.

The preventing means, used to regulate the lower limit of the capacitor voltage, can be implemented as a diode, connected in parallel to the capacitor, with its anode to ground. In some applications, however, the lower limit of the integrator voltage is preferably greater than zero, in order to secure a positive voltage across the capacitor. For example, when the clamp circuit is integrated in an IC, which is designed to operate from a single power supply, only positive voltages can be handled. To have maximum design flexibility, the actual RC integrator is kept externally. The output of the integrator, being connected to the internal clamp via one of the IC pins, must now be prevented from going negative.

In order to secure a positive voltage across the capacitor, the preventing means can be implemented as a clamp transistor having an emitter connected to a junction between said resistor and capacitor, a collector connected to a supply voltage, and a base connected to a base voltage. The base voltage can be fixed, or arranged to be compensated for any temperature variations.

The integrator according to the invention can advantageously be used for measuring the magnetic flux in a transformer, and especially in power supply topologies in which the transformer core excitation is only single sided, such as forward and flyback topologies. The flyback power supplies are very widely used within consumer electronics such as set-top boxes, satellite receivers, DVD players, and television applications.

This and other aspects of the present invention will now be described in more detail, with reference to the appended drawings showing a currently preferred embodiment of the invention.

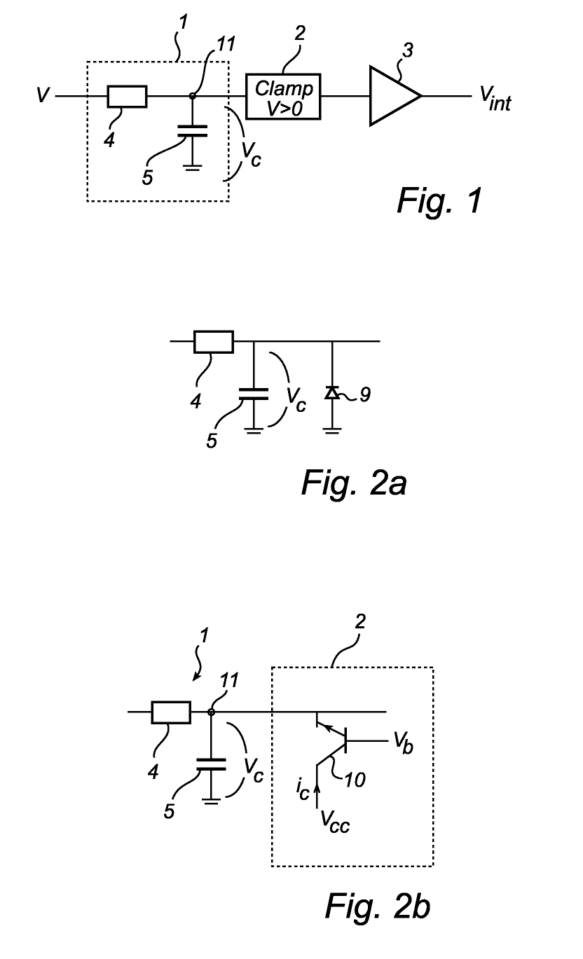

FIG. 1 is a schematic block diagram of an integrator according to an embodiment of the invention.

FIGS. 2a-b shows the integrator in FIG. 1 with a voltage securing means in the form of a voltage clamp.

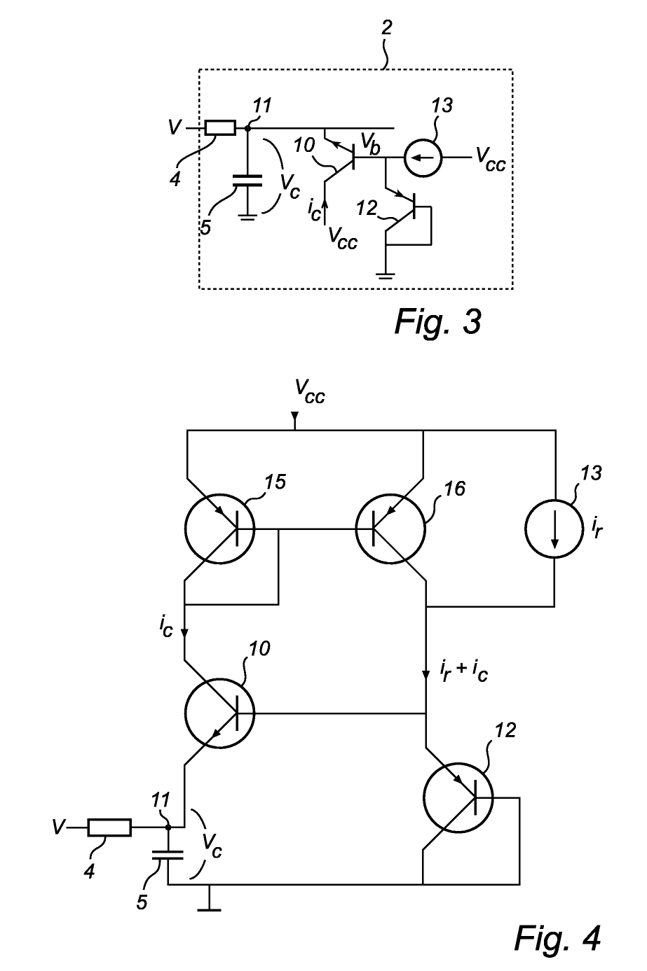

FIG. 3 shows the integrator in FIG. 2 with a voltage clamp further including temperature compensation.

FIG. 4 shows the integrator in FIG. 2 with a voltage clamp further including current feedback.

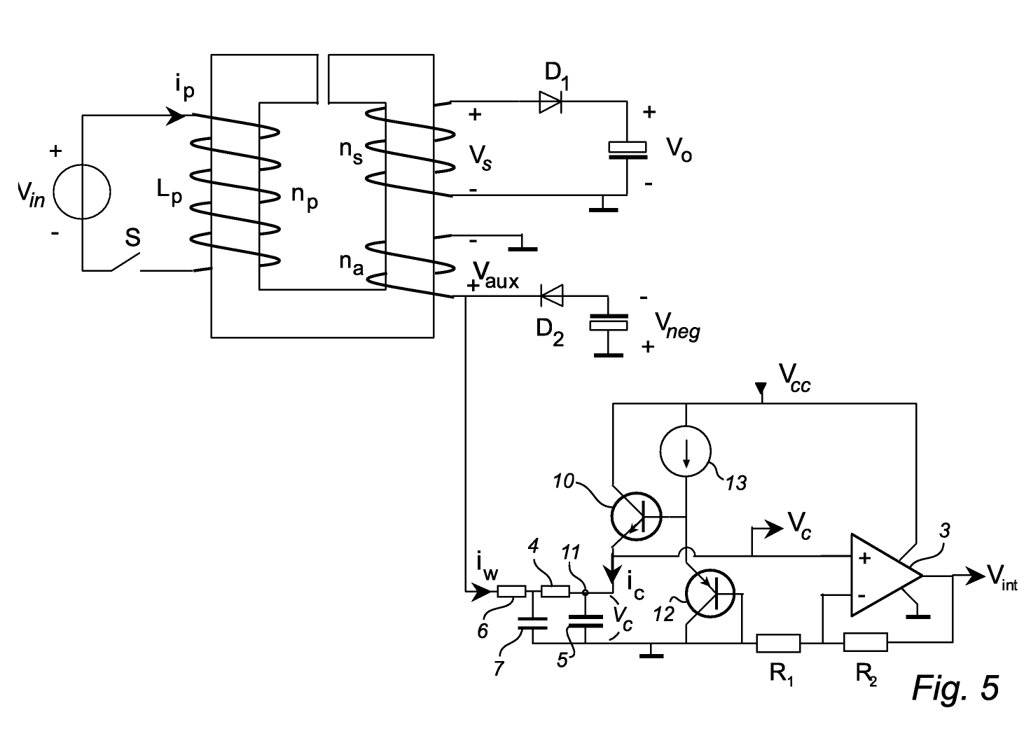

FIG. 5 shows an integrator similar to the one in FIG. 3, connected to an auxiliary winding of a flyback converter transformer.

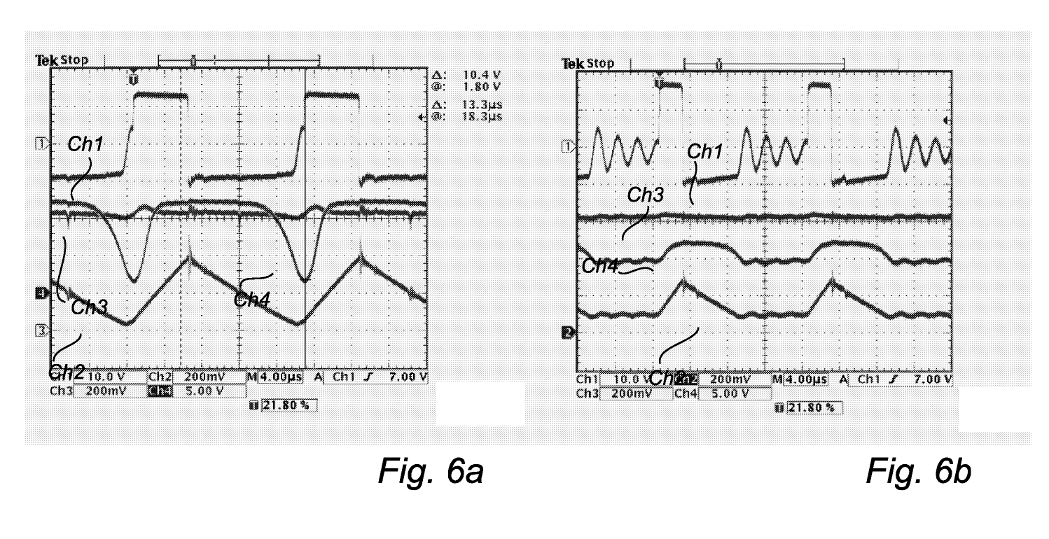

FIGS. 6a and 6b shows the performance of the integrator in FIG. 5, for two different flyback converter loads.

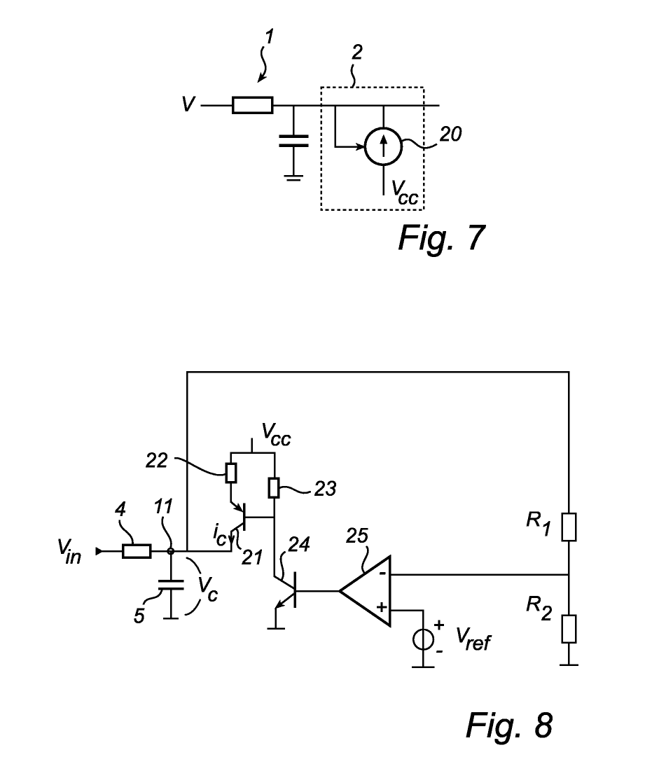

FIG. 7 shows the integrator in FIG. 1 with a voltage securing means in the form of a regulated current source.

FIG. 8 shows a realization of the regulated current source in FIG. 7.

FIG. 9 illustrates integration of the auxiliary voltage from the flyback converter in FIG. 5.

A schematic block diagram of an integrator according to the invention is shown in FIG. 1. An RC-filter 1 comprises a resistor 4 and a capacitor 5 connected in series between the input voltage and ground and the resistor and capacitor are dimensioned to act as an integrator. The filter 1 is followed by a block 2 ensuring that the voltage stays above a minimum level. The voltage can then be amplified by an amplifier 3, which is beneficial in many applications. A key aspect of the invention is to provide the voltage level securing means in block 2. In the following, several different ways to embody such a securing means will be described.

In a first embodiment, shown in FIGS. 2a and 2b, the regulation is provided by a simple clamp. In principle, and as shown in FIG. 2a, a diode 9 connected in parallel with the capacitor will work as a regulating clamp, preventing the capacitor voltage V_{C} to fall below −Vf, in which Vf represents the diode forward voltage (being typically 0.6V). However, as a positive voltage is desired here, a transistor is used as a clamp. FIG. 2b shows an NPN transistor 10, connected with its emitter to the junction 11 between the resistor 4 and capacitor 5 of the RC-filter 1, its collector to a supply voltage V_{cc}, and its base to a fixed voltage V_{b}. The clamp transistor 10 will cause a clamp current i_{c} that results in the desired regulation of the minimum voltage across the capacitor.

In an alternative embodiment of the clamp embodiment, shown in FIG. 3, the base of the transistor 10 is kept at a fixed voltage by a second transistor 12 and a current source 13. The transistor 12 is a PNP transistor having its emitter connected to the base of transistor 10 and its collector and base connected to ground. The current source is powered by a supply voltage V_{cc}, and connected to the emitter of transistor 12. In this case, the current from the current source 13 flows through the base-emitter junction of transistor 12, and the base voltage of the clamp transistor 10 is determined by the base-emitter voltage drop of transistor 12. Thereby. temperature compensation of the clamp current i_{c} is achieved.

In yet a further alternative of the clamp embodiment, shown in FIG. 4, current feedback is provided by two additional transistors 15 and 16. Transistors 15 and 16 together form a current mirror, which copies the collector current of transistor 10 into the emitter of transistor 12. The collector current of transistor 10, which is required to keep V_{C} above zero, now also flows through transistor 12. As a consequence, if higher collector current is required through transistor 10, the base-emitter voltage drop of transistor 10 increases. Thereby, the base voltage of transistor 10 increases, and the required higher collector current of transistor 10 is facilitated without a decrease of the minimum level of V_{C}. Thus, by applying such current feedback, the minimum level of V_{C} can be kept much more constant. The current source 13 is still needed to bias transistor 12 sufficiently when the collector current of transistor 10 is very small.

An implementation of an integrator according to the embodiment in FIG. 3 for measuring the magnetic flux in the transformer of a flyback power supply is shown in FIG. 5. The circuitry to the right of the RC filter (clamp, amplifier) can advantageously be implemented in an IC. One pin of the IC is then connected to the junction 11.

Besides the main output winding ns delivering the main output voltage Vₒ, use is made of a auxiliary winding nₐ from which a negative output voltage V_{neg} may be derived. The winding voltage Vₐᵤₓ of this auxiliary winding is used to derive a voltage being proportional to the transformer flux. The voltage Vₐᵤₓ is fed to the RC filter 1, being dimensioned in such a way that RC>>(tₒₙ+t_{fly}), where tₒₙ is the conduction time of the primary switch S and t_{fly} is the duration of the flyback stroke.

The transformer flux reaches zero (the transformer core is demagnetized) at the end of each flyback stroke t_{fly}. Immediately after the demagnetization, the primary inductance Lₚ starts oscillating with the parasitic capacitance of the primary switch, and an oscillation occurs in the voltage over the switch S. In order to minimize the switching losses in the primary switch, it is turned on every time in the “valley” of this sinusoid. In case of a self-oscillating flyback converter, a load decrease and/or an increase of the input voltage, causes the number of sinusoidal periods before each switch ON to increase.

The sinusoidal content of the voltage over the switch S will also be present in Vₐᵤₓ, and will therefore typically also be integrated when measuring the flux. With the integrator according to the invention, however, the sinusoidal part in Vₐᵤₓ will be damped to a large extent by the RC integrator, forming a low-pass filter 1.

As mentioned above, RC>>(tₒₙ+t_{fly}) to have a good integrating behavior. In general, the frequency of the sinusoid oscillation is much higher than the switching frequency of the flyback converter. If we denote the period time of the sinusoidal oscillation by T_{osc}, we have RC>>T_{osc} or

$${f}_{k} = \frac{1}{2 π RC} ≪ {f}_{osc} .$$

Here, fₖ is the −3 dB frequency of the RC filter and f_{osc}, is the frequency of the sinusoidal oscillation. This means that the RC integrator effectively damps the sinusoidal part in Vₐᵤₓ.

In a practical flyback converter, the voltage across the primary switch contains high frequency ringing just after the primary switch S turns off. This ringing is caused by the primary leakage inductance oscillating with the parasitic capacitance of the primary switch. The amplitude of the leakage ringing depends on the operating condition of the power supply, and is highest in case of minimum input voltage together with maximum load. This leakage ringing is to some extent being present in all transformer winding voltages. The amount of leakage ringing present in a secondary transformer winding depends on the coupling of this winding with the primary winding.

Therefore, some leakage ringing will also be present in the Vₐᵤₓ voltage, resulting in some distortion of the integrator output voltage. In order to reduce or eliminate this ringing, the RC-filter 1 can be preceded by an additional resistor 6 and capacitor 7, together forming a second RC-filter having a time constant R_{f}C_{f}. As the leakage ringing has a much higher frequency than the switching frequency of the flyback converter, the R_{f}C_{f} time constant can be selected much smaller than the RC time constant of the actual integrator filter 4, 5. This then means that the R_{f}C_{f} filter acts as a sole resistor R_{f} for frequencies close to the switching frequency of the converter (the impedance of C_{f} at the switching frequency is still large). Therefore, the actual integration is not disturbed by the addition of this leakage filter. The design constraint to obtain a true integral of the winding voltage Vₐᵤₓ now becomes (R+R_{f})C>>(tₒₙ+t_{fly}).

It should be noted that with only the filter 1, the V_{c} waveform would shift around zero depending on the input voltage Vᵢₙ and the load of the power supply. Here, the clamp transistor 10 prevents V_{c} from going negative, and in this way an automatic initialization of V_{c} at the start of each switching cycle is accomplished.

Depending on the auxiliary turns nₐ, the amplitude of V_{c} may be too small for practical use and a non-inverting amplifier 3, feedback with two resistors R1 and R2, may be needed.

FIGS. 6a and 6b show two relevant measurements carried out in the setup of FIG. 5, with full and reduced load of the self-oscillating flyback power supply, respectively. The plots show the winding voltage, Vₐᵤₓ (Ch1), integrator output voltage, V_{C} (Ch2), Base voltage of transistor 10 (Ch3) and current through transistor 10, i_{C} (Ch4) (ground level of Ch2 is the same as Ch3).

The measurements of FIGS. 6a and 6b show that the clamp current i_{c} (Ch4) depends heavily on the operating conditions of the power supply. The amount of current needed (peak value of i_{c}) can be set very easily with the selection of the resistors 4 and 6. Higher values of the resistances of the resistors 4 and 6 lead to lower levels of i_{c}.

FIGS. 6a and 6b also show that the lower level of V_{C} is slightly above zero, as required. But, this lower level shifts somewhat dependent on the operating conditions of the power supply. This is caused by the fixed base voltage of clamp transistor 10; if less clamp current i_{C} is required, the base-emitter voltage of the clamp transistor 10 must decrease and, as a consequence, the emitter voltage must rise. Therefore, the lower level of V_{C} shifts upward when less clamp current i_{C} is required as FIG. 6b shows.

If this shift of the lower level of V_{C} is unacceptable, use can be made of the implementation shown in FIG. 4. As an alternative, the clamp transistor 10 can be replaced by a voltage controlled current source, which is controlled as to keep the lower level of V_{C} constant. Such a voltage controlled current source is shown in FIG. 7 with reference 20, and is a further embodiment of the block 2 in FIG. 1.

FIG. 8 shows a practical realization of the regulated current source 20. Here, a PNP transistor 21 is connected with its collector to the junction between the resistor 4 and capacitor 5 of the filter 1, and its emitter and base to a supply voltage V_{cc} via two resistors 22 and 23. The resistors serve to define the relation between the current i_{c} of transistor 21 and the collector current of transistor 24. Further, the base of the PNP transistor 21 is connected to the collector of a NPN transistor 24, the emitter of which is connected to ground. The base of the NPN transistor is connected to the output of an operational amplifier 25, having its positive input connected to a reference voltage, V_{ref}. The negative input of the op-amp 25 is connected to the voltage V_{C} across the capacitor 5 via a voltage divider provided by two resistors R1 and R2.

The circuit in FIG. 8 thus regulates the minimum voltage Vc across the integrator capacitor 5 by feeding back this voltage to the op-amp 25. If the capacitor voltage V_{C} tends to go below a reference value, set by the resistors R1 and R2, the operational amplifier 25 output goes high and both transistors 21, 24 conduct. The opamp 25 operates as an error amplifier in a feedback system. Frequency compensation may be required to stabilize the feedback system (not shown).

Note that the opamp 25 operates as an error amplifier only when the voltage V_{c} tends to decrease below a reference value, given by V_{ref}(R1+R2)/R2. During a large part of the switching period, the voltage V_{c} is higher, and the opamp output is low. This means that during each switching period the feedback system is switched on and off, and the error amplifier output reaches its steady-state value only after a certain settling time. As a result, operation of this voltage controlled current source is limited to relatively low frequencies. This problem can of course be overcome, but available solutions increase the complexity of the system.

The person skilled in the art realizes that the present invention by no means is limited to the preferred embodiments described above. On the contrary, many modifications and variations are possible within the scope of the appended claims. For example, the bipolar transistors used in the embodiments above can be replaced by field effect transistors or other transistors, as long as suitable adjustment of the circuits are made.

Further, the integrator has here been described mainly in relation to measurements of the magnetic flux in a transformer. Such measurements can be used to detect the demagnetization of the flyback transformer by comparing the integrator output voltage V_{C} with a reference voltage. This reference voltage equals the minimum level of the integrator output voltage, which may be zero. Now, when the integrator output voltage decreases down to the reference voltage, the comparator collapses, indicating the end of the flyback stroke. In this application, the approximation of the integration must be very good as to avoid timing errors (tₓ in FIG. 9). Also, it is important to avoid shifting of the minimum level in the integrator output voltage. This means the clamp should fulfill more stringent requirements.

However, the integrator may of course advantageously be used in other applications, where an integration of a periodic voltage is required. One example is the derivation of a triangle waveform, which is synchronized with the switching frequency of the power supply. As this triangle wave, with the use of an integrator according to the invention, is kept above zero, it can be used in a PWM control system.

1. A voltage integrator, comprising a resistor (4) and a capacitor (5) connected in series between an input voltage (V) and ground, wherein the resistance (R) of said resistor and the capacitance (C) of said capacitor are adapted such that a voltage (V_{C}) across said capacitor approximates an integral of said input voltage (V), characterized in means for preventing said capacitor voltage (V_{C}) from falling below a lower limit.

2. The voltage integrator according to claim 1, wherein the RC time constant of the filter (1) is significantly larger than the time interval to be integrated, preferably 5-10 times larger.

3. The voltage integrator according to claim 1, wherein said lower limit is greater than zero.

4. The voltage integrator according to claim 1, wherein said preventing means comprises a clamp transistor (10) having an emitter connected to a junction (11) between said resistor (4) and capacitor (5), a collector connected to a supply voltage (V_{cc}), and a base connected to a fixed base voltage (V_{b}).

5. The voltage integrator according to claim 4, wherein said securing means further comprise a voltage source arranged to provide said fixed voltage (V_{b}).

6. The voltage integrator according to claim 4, wherein said preventing means further comprise a current source (13), connected to the base of the clamp transistor (10), and a second transistor (12) having an emitter connected to the base of the clamp transistor (10) and a collector and base connected to ground.

7. The voltage integrator according to claim 6, further comprising a third transistor (15), having a collector and a base connected to the collector of the first transistor (10), and an emitter connected to a supply voltage (V_{cc}), and a fourth transistor (16), having a collector connected to the base of the first transistor (10), a base connected to the base of the third transistor (15), and an emitter connected to the supply voltage (V_{cc}).

8. The voltage integrator according to claim 1, wherein said preventing means is a current source controlled by a feedback of the capacitor voltage (V_{C}), thereby regulating the lower limit of said capacitor voltage (V_{C}).

9. The voltage integrator according to claim 8, wherein said voltage controlled current source comprises:
an operational amplifier (25) having its negative input connected to a feedback of the capacitor voltage (V_{C}) and its positive input connected to a reference voltage, V_{ref},
a first transistor (24) having its base connected to the output of the operational amplifier (25), its emitter connected to ground, and its collector connected to a supply voltage (V_{cc}) via a first resistor (23), and
a second transistor (21) having its base connected to the collector of the first transistor (24), its emitter connected to a supply voltage (V_{cc}) via a second resistor (22), and its collector connected to a junction (11) between the resistor (4) and capacitor (5).

10. The voltage integrator according to claim 1, wherein said preventing means is a diode (9) connected parallel to the capacitor (5) with its anode to ground.

11. The voltage integrator according to claim 1, further comprising an amplifier (3) for amplifying the capacitor voltage (V_{C}).

12. A device for measuring the magnetic flux in a transformer, comprising an integrator according to claim 1 connected to an auxiliary winding voltage (Vₐᵤₓ) of said transformer.

13. A power converter, comprising a transformer and a device according to claim 12.

14. A power converter according to claim 13, implemented as a flyback topology.
